(19) United States
(12) Patent Application Publication
(10) Pub. No.: US 2020/0068750 A1
(43) Pub. Date: Feb. 27, 2020

(54) ELECTRONIC CIRCUIT MODULE MANUFACTURING METHOD AND ELECTRONIC CIRCUIT MODULE

(71) Applicant: Murata Manufacturing Co., Ltd., Nagaokakyo-shi (JP)

(72) Inventor: Hirokazu YAZAKI, Nagaokakyo-shi (JP)

(21) Appl. No.: 16/666,601

(22) Filed: Oct. 29, 2019

Related U.S. Application Data
(63) Continuation of application No. PCT/JP2018/017437, filed on May 1, 2018.

(30) Foreign Application Priority Data
May 10, 2017 (JP) 2017-094311

(51) Int. Cl. H05K 9/00; H05K 3/00; H05K 1/02; H05K 3/36

(52) U.S. Cl. CPC H05K 9/0024; H05K 3/0067; H05K 3/368; H05K 1/023; H05K 9/0084

(57) ABSTRACT

A manufacturing method including mounting a ceramic plate on a circuit board such that the ceramic plate can be prevented from falling over. An electronic circuit module manufacturing method includes mounting a ceramic plate including a resin layer on a principal surface of a circuit board in such a manner that a principal surface of the ceramic plate is perpendicular or substantially perpendicular to the principal surface of the circuit board, and removing the resin layer from the principal surface of the ceramic plate mounted on the circuit board. In the step of mounting, the ceramic plate is supported by the resin layer and is thus prevented from falling over.

### CROSS REFERENCE TO RELATED APPLICATIONS

This application claims the benefit of priority to Japanese Patent Application No. 2017-094311 filed on May 10, 2017 and is a Continuation Application of PCT Application No. PCT/JP2018/017437 filed on May 1, 2018. The entire contents of each application are hereby incorporated herein by reference.

### BACKGROUND OF THE INVENTION

### 1. Field of the Invention

The present invention relates to a method of manufacturing an electronic circuit module that includes a ceramic plate mounted perpendicularly or substantially perpendicularly to a principal surface of a circuit board. More specifically, the present invention relates to an electronic circuit module manufacturing method that is an easy and highly productive manufacturing method with which, in the step of mounting a ceramic plate on a circuit board, the ceramic plate can be prevented from falling over.

### 2. Description of the Related Art

Japanese Unexamined Patent Application Publication No. 2004-140035 discloses a typical electronic circuit module widely used in electronic devices. FIG. 16 illustrates an electronic circuit module 1000 disclosed in Japanese Unexamined Patent Application Publication No. 2004-140035.

The electronic circuit module 1000 includes a circuit board 101.

Shield members 102 and 103 are made of metal and mounted on a principal surface of the circuit board 101. The shield member 102 is a case outer periphery member (i.e., case body). The shield members 103 are case inner partitions. The outer periphery member reduces transmission of noise between inside and outside of the case. The partitions each reduce transmission of noise between both principal surfaces thereof. The electronic circuit module 1000 is characterized in that a magnesium alloy is used for the shield members 102 and 103. In typical electronic circuit modules, however, iron, aluminum, or other material are often used for the shield members 102 and 103.

The electronic circuit module 1000 is partitioned by the shield members 102 and 103 into a plurality of mounting regions 104. Electronic components 105 are each mounted in one of the mounting regions 104 on the principal surface of the circuit board 101.

The electronic circuit module 1000 is disadvantageous in that since the shield members 102 and 103, which are made of metal, may develop a short circuit if the electronic components 105 are mounted close to them, the electronic components 105 need to be mounted at a certain distance from the shield members 102 and 103. This creates dead space in the mounting regions 104 and results in an increased size of the electronic circuit module 1000.

The electronic circuit module 1000 is also disadvantageous in that since the shield members 102 and 103, which form a metal structure, need to be thick to some extent, the increased thickness of the shield members 102 and 103 results in reduced space in the mounting regions 104.

The inventors of preferred embodiments of the present invention experimented with the possibility of using a thin ceramic plate as a case outer periphery member, or as a case inner partition, of an electronic circuit module. If shielding properties that reduce the transmission of noise are required, then a conductive shield layer may be added to a principal surface. Even in the case of forming such a conductive shield layer, an electronic component can be mounted close to a principal surface including no conductive shield layer provided thereon, because of the reduced risk of short circuits. Thus, no dead space is created in the mounting regions, and a compact electronic circuit module can be produced.

However, this method has a problem in that, since the ceramic plate is thinner, it is difficult to perform the step of mounting the ceramic plate on the principal surface of the circuit board.

That is, the ceramic plate is mounted on the circuit board with an adhesive, or by providing an electrode in advance on an end surface of the ceramic plate in contact with the circuit board and then applying solder or conductive adhesive. However, the thin ceramic plate often falls over in this step and cannot be properly mounted on the circuit board. This means that when the ceramic plate is used as a case outer periphery member or as a case inner partition, the electronic circuit module is difficult to manufacture and suffers a high rejection rate, and thus the resulting productivity is low.

### SUMMARY OF THE INVENTION

Electronic circuit module manufacturing methods according to preferred embodiments of the present invention each overcome the problems described above.

A preferred embodiment of the present invention provides a method of manufacturing an electronic circuit module that includes a circuit board and a ceramic plate mounted on the circuit board. The electronic circuit module manufacturing method includes the steps of making a mother ceramic substrate by firing, forming a resin layer on at least one principal surface of the mother ceramic substrate, cutting the mother ceramic substrate including the resin layer thereon in a stacking direction of the resin layer and the mother ceramic substrate into pieces, each of the pieces including the ceramic plate with the resin layer thereon, mounting the ceramic plate including the resin layer thereon on a principal surface of the circuit board such that a principal surface of the ceramic plate is perpendicular or substantially perpendicular to the principal surface of the circuit board, and removing the resin layer from the principal surface of the ceramic plate mounted on the circuit board.

That is, the electronic circuit module manufacturing method according to the above preferred embodiment of the present invention is configured such that in the step of mounting the ceramic plate on the circuit board, the ceramic plate has a small thickness and is supported by the resin layer formed thereon, so that it is mounted on the circuit board without falling over. After the mounting, the resin layer no longer required is removed from the ceramic plate.

An electronic circuit module manufacturing method according to a preferred embodiment of the present invention preferably further includes a step of forming a conductive shield layer on at least one principal surface of the mother ceramic substrate. Adding the conductive shield layer enables the ceramic plate to reduce transmission of noise between both principal surfaces thereof. When both the resin layer and the conductive shield layer are formed on the same principal surface of the mother ceramic substrate, the conductive shield layer is formed on the mother ceramic substrate and the resin layer is formed on the conductive shield layer. Note that the resin layer and the conductive shield layer do not necessarily need to be formed on the same principal surface of the mother ceramic substrate. That is, the resin layer and the conductive shield layer may be formed on the respective principal surfaces of the mother ceramic substrate.

An electronic circuit module manufacturing method according to a preferred embodiment of the present invention may further include a step of forming a graphite layer on a principal surface of the conductive shield layer formed on the mother ceramic substrate. In this case, because of a very high heat dissipation effect of the graphite layer, the ceramic plate (conductive shield layer) can be prevented from being heated to a high temperature. When both the resin layer and the graphite layer are formed on the same principal surface of the mother ceramic substrate, it is preferable that the graphite layer be formed on the conductive shield layer, and that the resin layer be formed on the graphite layer.

The mother ceramic substrate is preferably a multilayer substrate formed by stacking a plurality of ceramic layers. In this case, the thickness of the mother ceramic substrate (ceramic plate) can be easily set to any value. Also, a wiring electrode can be formed inside the mother ceramic substrate (ceramic plate). However, that the mother ceramic substrate is not limited to a multilayer substrate and may be a single-layer substrate.

It is also preferable that the mother ceramic substrate is made of a magnetic ceramic material, such as a magnetic ferrite ceramic material. In this case, the ceramic plate made of a magnetic ceramic material can reduce transmission of low-frequency noise between both principal surfaces thereof.

The ceramic plate may define a case outer periphery member or a case inner partition. That is, the ceramic plate may define a wall portion, such as a case outer periphery member or a case partition of the electronic circuit module.

It is preferable that the step of making the mother ceramic substrate includes forming a conductive via in the mother ceramic substrate, and that the cutting of the mother ceramic substrate into pieces, each being the ceramic plate, enables a cross-section of the conductive via to be exposed on at least one of a first end surface and a second end surface of the ceramic plate, the first end surface being an end surface to be mounted on the circuit board, the second end surface being opposite the first end surface to be mounted on the circuit board. In this case, the ceramic plate can be mounted on the circuit board by joining the conductive via exposed on the first end surface of the ceramic plate to be mounted on the circuit board, with solder or conductive adhesive, to a mounting electrode formed on the principal surface of the circuit board. Also, a lid member made of metal, or a lid member formed by a ceramic plate having a conductive shield layer thereon, can be attached, with solder or conductive adhesive, to the conductive via exposed on the second end surface opposite the first end surface to be mounted on the circuit board.

In this case, it is also preferable that cross-sections of different conductive vias are exposed on the respective first and second end surfaces of the ceramic plate, the first end surface being an end surface to be mounted on the circuit board, the second end surface being opposite the first end surface to be mounted on the circuit board. It is also preferable that the step of making the mother ceramic substrate includes forming a wiring electrode in the mother ceramic substrate, the wiring electrode electrically connecting the different conductive vias. In this case, a lid member made of metal, or a conductive shield layer of a lid member obtained by forming the conductive shield layer on a ceramic plate, can be connected to a ground electrode on the circuit board with one conductive via, the wiring electrode, and the other conductive via in the ceramic plate interposed therebetween. This improves the shielding effect of the lid member made of metal, or the conductive shield layer of the lid member obtained by forming the conductive shield layer on the ceramic plate.

It is also preferable that the electronic circuit module manufacturing method further includes a step of forming at least one of a slit and a groove in a principal surface of an unfired mother ceramic substrate before the mother ceramic substrate is made by firing, or in a principal surface of the mother ceramic substrate after the mother ceramic substrate is made by firing, the slit penetrating between both principal surfaces, the groove opening on one principal surface, at least one of the slit and the groove be formed in each of the ceramic plates formed by the cutting. The step of mounting the ceramic plate on the circuit board involves bending the ceramic plate at the slit or groove before the ceramic plate is mounted on the circuit board. This further facilitates the step of mounting the ceramic plate on the circuit board, and also facilitates mounting the ceramic plate on the circuit board in a complex shape (e.g., in the shape of a polygon with five or more sides).

It is preferable that opposite inner surfaces of the slit, or opposite inner surfaces of the groove, are inclined such that an angle of about 90° is provided therebetween. This prevents the situation where the ceramic plate cannot be bent due to contact between different portions of the inner surface thereof, and enables the ceramic plate to be easily bent into a right angle (90°). It is also possible to prevent creation of a gap at the bent portion of the ceramic plate. This applies to the case where the ceramic plate is bent to an approximately 90° angle. By setting the inclination of opposite inner surfaces of each groove in accordance with the bend angle, the ceramic plate can be easily mounted in a complex shape.

The step of removing the resin layer from the principal surface of the ceramic plate mounted on the circuit board may include continuously peeling off the resin layer formed in an elongated shape on the principal surface of the ceramic plate, the peeling starting at one end portion of the resin layer. This facilitates removal of the resin layer from the principal surface of the ceramic plate. The method for removing the resin layer is not limited to this. A different method may be employed, with which the resin layer is dissolved in a solvent, or melted away by heat applied thereto.

Preferred embodiments of the present invention are also directed to electronic circuit modules. An electronic circuit module according to a preferred embodiment of the present invention can be manufactured by an electronic circuit module manufacturing method according to a preferred embodiment of the present invention described above. Specifically, an electronic circuit module according to a preferred embodiment of the present invention includes a circuit board including a principal surface, an electronic component mounted on the principal surface of the circuit board, and a wall portion mounted on the principal surface of the circuit board, the wall portion surrounding the electronic component. The wall portion includes a bottom surface adjacent to and opposing the principal surface of the circuit board, a top surface opposite the bottom surface, and a plurality of side surfaces connecting the bottom surface to the top surface. The wall portion includes a multilayer structure defined by stacking a plurality of ceramic layers, and the side surfaces of the wall portion are perpendicular or substantially perpendicular to the principal surface of the circuit board.

It is also preferable that the wall portion includes a conductive shield layer on at least one of the side surfaces in a pair, the side surfaces being opposite in a stacking direction of the plurality of ceramic layers. In this case, adding the conductive shield layer enables the wall portion to reduce transmission of noise between both principal surfaces thereof.

It is also preferable that the electronic circuit module further includes a graphite layer on the conductive shield layer. In this case, because of a very high heat dissipation effect of the graphite layer, the wall portion (which preferably defines a conductive shield layer) can be prevented from being heated to a high temperature.

It is also preferable that the plurality of ceramic layers contain magnetic ferrite. In this case, the wall portion made of a magnetic ceramic material can reduce transmission of low-frequency noise between both principal surfaces thereof.

It is also preferable that the wall portion is a case outer periphery member or a case inner partition.

It is also preferable that the wall portion includes a conductive via, and that a cross-section of the conductive via be exposed on at least one of the bottom surface and the top surface of the wall portion. In this case, the wall portion can be mounted on the circuit board by joining the conductive via exposed on the end surface of the wall portion to be mounted on the circuit board, with solder or conductive adhesive, to a mounting electrode on the principal surface of the circuit board.

It is also preferable that cross-sections of different conductive vias are exposed on the respective bottom and top surfaces of the wall portion, and that the wall portion includes a wiring electrode connecting the different conductive vias. In this case, a lid member made of metal, or a conductive shield layer of a lid member obtained by providing the conductive shield layer on a wall portion, can be connected to a ground electrode on the circuit board, with one conductive via, the wiring electrode, and the other conductive via in the wall portion interposed therebetween.

It is also preferable that the electronic circuit module includes a plurality of wall portions, and that the plurality of wall portions include respective portions extending in different directions in a plan view, the portions being in contact with each other at respective ends of the wall portions. This enables the wall portions (e.g., case outer periphery members or partitions) to have a closed structure.

With the electronic circuit module manufacturing methods according to preferred embodiments of the present invention, the ceramic plate can be prevented from falling over in the step of mounting the ceramic plate on the circuit board. This facilitates manufacture, lowers the rejection rate, and improves productivity in the manufacture of electronic circuit modules.

The electronic circuit modules according to preferred embodiments of the present invention can be easily manufactured by the electronic circuit module manufacturing methods according to preferred embodiments of the present invention.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is an exploded perspective view of an electronic circuit module 100 that can be manufactured by an electronic circuit module manufacturing method according to a preferred embodiment of the present invention.

FIG. 2 is an exploded perspective view of another electronic circuit module 200 that can be manufactured by the electronic circuit module manufacturing method according to a preferred embodiment of the present invention.

FIG. 3 is an exploded perspective view of another electronic circuit module 300 that can be manufactured by the electronic circuit module manufacturing method according to a preferred embodiment of the present invention.

FIG. 4 is a perspective view of a ceramic plate 2 used in the electronic circuit module 100.

FIGS. 5A to 5C are perspective views each illustrating a step performed in an electronic circuit module manufacturing method according to a first preferred embodiment of the present invention.

FIGS. 6D to 6F are perspective views following FIG. 5C and each illustrating a step performed in the electronic circuit module manufacturing method according to the first preferred embodiment of the present invention.

FIGS. 7G to 71 are perspective views following FIG. 6F and each illustrating a step performed in the electronic circuit module manufacturing method according to the first preferred embodiment of the present invention.

FIG. 8A is a perspective view illustrating a step performed in an electronic circuit module manufacturing method according to a second preferred embodiment of the present invention.

FIG. 9B is a perspective view following FIG. 8A and illustrating a step performed in the electronic circuit module manufacturing method according to the second preferred embodiment of the present invention.

FIGS. 10C and 10D are perspective views following FIG. 9B and each illustrating a step performed in the electronic circuit module manufacturing method according to the second preferred embodiment of the present invention.

FIGS. 11E and 11F are perspective views following FIG. 10D and each illustrating a step performed in the electronic circuit module manufacturing method according to the second preferred embodiment of the present invention.

FIGS. 12A and 12B are perspective views each illustrating a step performed in an electronic circuit module manufacturing method according to a third preferred embodiment of the present invention.

FIGS. 13C and 13D are perspective views following FIG. 12B and each illustrating a step performed in the electronic circuit module manufacturing method according to the third preferred embodiment of the present invention.

FIGS. 14E and 14F are perspective views following FIG. 13D and each illustrating a step performed in the electronic circuit module manufacturing method according to the third preferred embodiment of the present invention.

FIGS. 15A and 15B are perspective views each illustrating a step performed in an electronic circuit module manufacturing method according to a fourth preferred embodiment of the present invention.

FIG. 16 is an exploded perspective view of an electronic circuit module 1000 disclosed in Japanese Unexamined Patent Application Publication No. 2004-140035.

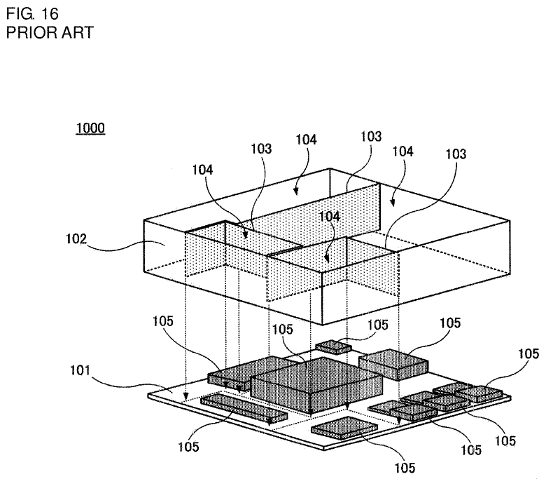

### DETAILED DESCRIPTION OF THE PREFERRED EMBODIMENTS

Preferred embodiments of the present invention will now be described in detail with reference to the drawings.

The preferred embodiments described herein are merely exemplary preferred embodiments of the present invention, and the present invention is not limited to the preferred embodiments described herein. Techniques described in different preferred embodiments may be performed in a combined manner, and such combinations are also included in the present invention. The drawings are provided to help understand the preferred embodiments, and may not necessarily be drawn exactly to scale. For example, the ratios of dimensions of, or between, elements depicted in the drawings may differ from the ratios of dimensions mentioned in the description. Also, the elements mentioned in the description may be omitted or reduced in number in the drawings.

### First Preferred Embodiment

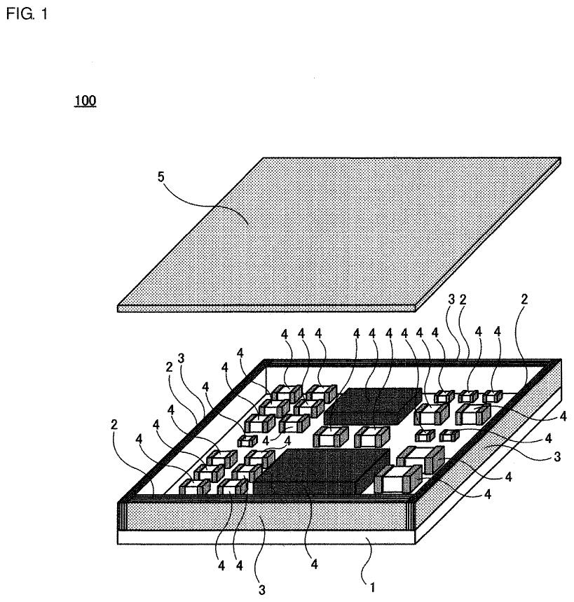

FIGS. 1 to 3 illustrate electronic circuit modules 100, 200, and 300 manufactured by an electronic circuit module manufacturing method according to a first preferred embodiment of the present invention. Note that FIGS. 1 to 3 are exploded perspective views each illustrating a lid member 5 in a detached state.

As illustrated in FIG. 1, the electronic circuit module 100 includes a circuit board 1. The circuit board 1 may be made of any material and is preferably made of, for example, a ceramic or resin material. Also, the circuit board 1 may have any structure, and may be either a multilayer or single-layer substrate.

The circuit board 1 preferably includes, on the lower principal surface thereof, outer electrodes (not shown) used to mount the electronic circuit module 100, for example, on a circuit board of an electronic device. The circuit board 1 preferably includes, on the upper principal surface thereof, mounting electrodes (not shown) used to mount electronic components 4 (described below). The outer electrodes are electrically connected to the mounting electrodes by predetermined circuit wires formed inside the circuit board 1.

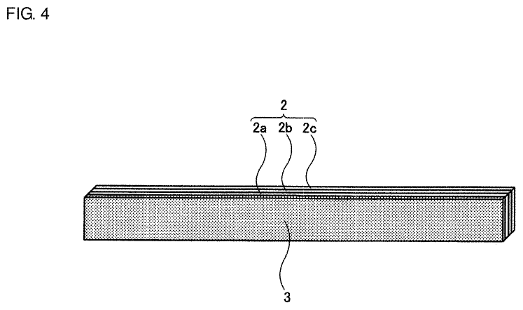

As case outer periphery members, four ceramic plates 2 are preferably mounted along the outer edge of the upper principal surface of the circuit board 1. FIG. 4 is an enlarged view of one of the ceramic plates 2. The ceramic plate 2 preferably has a multilayer structure formed by stacking three ceramic layers 2a, 2b, and 2c. A conductive shield layer 3 is provided on one principal surface of the ceramic plate 2. The conductive shield layer 3 is preferably connected to the ground potential.

Although the ceramic plates 2 may be made of any ceramic material, a magnetic ceramic material (magnetic ferrite ceramic material) is preferably used in the present preferred embodiment. Although the ceramic plates 2 may have any dimensions, the ceramic plates 2 are preferably, for example, about 100 μm thick and about 700 μm high in the present preferred embodiment. The ceramic plates 2 are each adjusted in length to fit the outer perimeter of the circuit board 1.

Although the conductive shield layer 3 may be made of any material, a metal (including a metal alloy) primarily including copper, for example, is preferably used in the present preferred embodiment. The conductive shield layer 3 may have any thickness, and is preferably, for example, about 20 μm thick in the present preferred embodiment. The surface of the conductive shield layer 3 may be plated, for example, with nickel, palladium, or gold.

As illustrated in FIG. 1, the ceramic plates 2 are mounted along the outer edge of the upper principal surface of the circuit board 1, with their principal surfaces each including the conductive shield layer 3 provided thereon facing outward. For example, an adhesive is used to mount the ceramic plates 2 on the circuit board 1. Alternatively, the end surfaces of the ceramic plates 2 in contact with the circuit board 1 may be provided with electrodes (e.g., conductive vias) provided in advance, so that the electrodes are joined with solder or conductive adhesive to the mounting electrodes provided on the upper principal surface of the circuit board 1. The mounting electrodes may be ground electrodes, to which the conductive shield layers 3 are connected.

Adjacent ones of the ceramic plates 2 extend in different directions in a plan view, and are in contact with each other at their respective end portions. That is, the case outer periphery members (wall portions) defined by the ceramic plates 2 have a closed structure.

A plurality of electronic components 4 are mounted in a mounting region of the upper principal surface of the circuit board 1, surrounded by the case outer periphery members defined by the ceramic plates 2. The electronic components 4 are mounted by soldering onto the mounting electrodes provided on the upper principal surface of the circuit board 1.

The lid member 5 made of metal is joined to the upper end surfaces of the case outer periphery members defined by the ceramic plates 2. For example, an adhesive is used to join the lid member 5. Alternatively, the upper end surfaces of the ceramic plates 2 may include electrodes (e.g., conductive vias) provided in advance, so that the lid member 5 is joined with solder or conductive adhesive to the electrodes. Instead of being made of metal, the lid member 5 may be a ceramic member, for example, like the ceramic plate 2, including a conductive shield layer provided on a principal surface thereof.

The electronic circuit module 100 can reduce noise transmission between the outside and the mounting region where the electronic components 4 are mounted, because (1) the case outer periphery members are defined by the ceramic plates 2 each including the conductive shield layer 3 thereon, and the lid member 5 made of metal is joined to the upper end surfaces of the case outer periphery members; and (2) the ceramic plates 2 are made of a magnetic ceramic material. The conductive shield layer 3 on each of the ceramic plates 2 primarily reduces transmission of high-frequency noise. The ceramic plates 2 made of a magnetic ceramic material primarily reduce transmission of low-frequency noise.

Also, in the electronic circuit module 100, the case outer periphery members are preferably defined by the ceramic plates 2, with their principal surfaces each including the conductive shield layer 3 thereon facing outward and the other principal surfaces each including no conductive shield layer 3 thereon facing inward (i.e., facing toward the mounting region where the electronic components 4 are mounted). Since this reduces the risk of short circuits, the electronic components 4 can be mounted closer to the ceramic plates 2. The electronic circuit module 100 thus has no dead space in the mounting region and is able to achieve a size reduction.

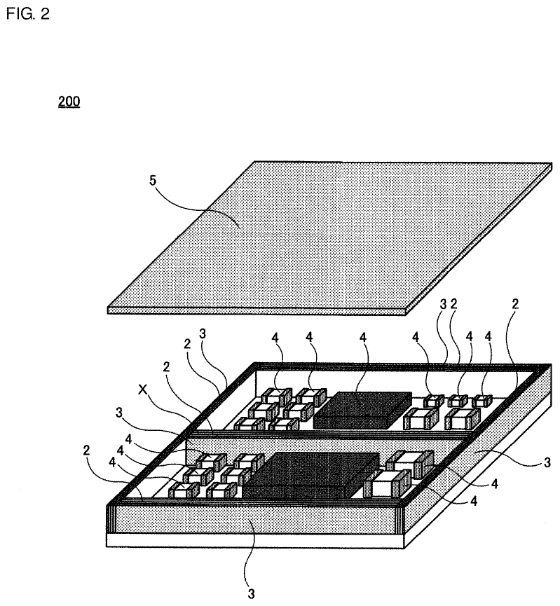

FIG. 2 illustrates an electronic circuit module 200 that is a modification of the electronic circuit module 100. The electronic circuit module 200 is obtained by adding a component to the electronic circuit module 100. Specifically, the electronic circuit module 200 is obtained by adding an inner partition X to the case. In the electronic circuit module 200, the ceramic plate 2 including the conductive shield layer 3 on one principal surface thereof defines and functions as the partition X. Thus, in the electronic circuit module 200, transmission of noise between both principal surfaces of the partition X is reduced. When, for example, two ceramic plates 2 are bonded together, with the conductive shield layers 3 facing inward, the risk of short circuits with the electronic components 4 can be reduced.

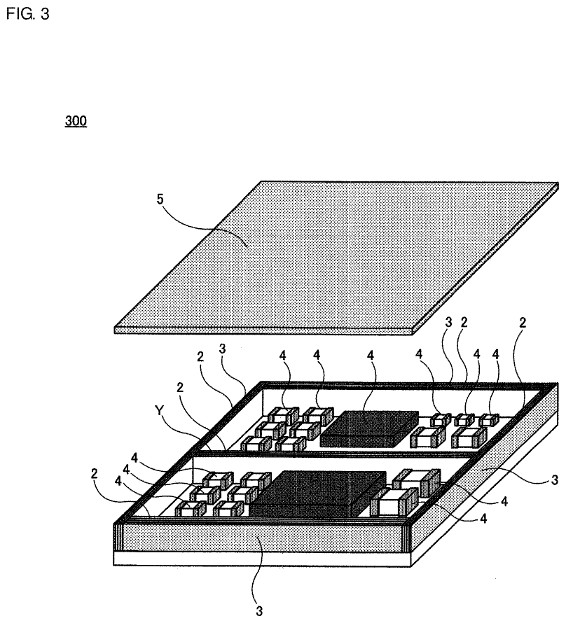

FIG. 3 illustrates an electronic circuit module 300 that is another modification of the electronic circuit module 100. The electronic circuit module 300 is also obtained by adding a component to the electronic circuit module 100. Specifically, the electronic circuit module 300 is obtained by adding an inner partition Y to the case. In the electronic circuit module 300, the ceramic plate 2 without any conductive shield layer 3 provided thereon defines and functions as the partition Y. This reduces the risk of short circuits and allows the electronic components 4 to be mounted closer to the partition Y. Therefore, no dead space is created in the mounting region in the case. Although the partition Y, which does not include any conductive shield layer 3 provided thereon, cannot reduce transmission of high-frequency noise, the ceramic plate 2 including a magnetic ceramic material can reduce transmission of low-frequency noise. The ceramic plate 2 without any conductive shield layer 3 thereon can be made by skipping the step of applying copper paste to one principal surface of an unfired mother ceramic substrate 12′ (described below).

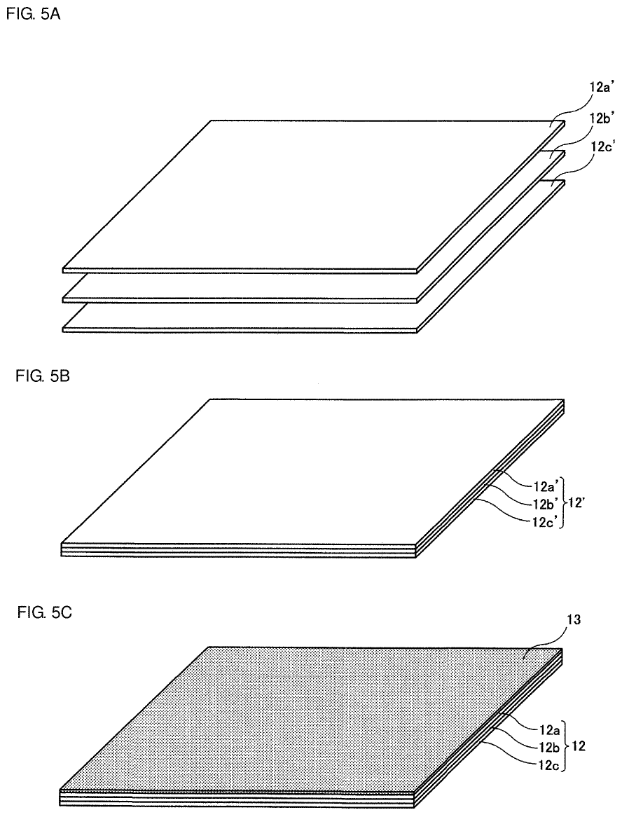

An electronic circuit module manufacturing method according to the first preferred embodiment will now be described with reference to FIG. 5A to FIG. 7I. The electronic circuit modules 100, 200, and 300 described above can be manufactured by the electronic circuit module manufacturing method according to the first preferred embodiment.

First, as illustrated in FIG. 5A, ceramic green sheets 12a′, 12b′, and 12c′ are prepared. In the present preferred embodiment, a ferrite primarily including iron oxide and including at least one of zinc, nickel, and copper, for example, is preferably used to form the ceramic green sheets 12a′, 12b′, and 12c′. More specifically, powder of the ferrite, a binder, and a solvent are mixed to form a ceramic slurry, which is then preferably applied, for example, by a doctor blade method onto a film to obtain the ceramic green sheets 12a′, 12b′, and 12c′.

Next, as illustrated in FIG. 5B, the ceramic green sheets 12a′, 12b′, and 12c′ are stacked, pressed, and heated to obtain the unfired mother ceramic substrate 12′.

After application of copper paste to one principal surface of the unfired mother ceramic substrate 12′, the entire unfired mother ceramic substrate 12′ is fired to obtain, as illustrated in FIG. 5C, a mother ceramic substrate 12 including a conductive shield layer 13 formed on one principal surface thereof. The mother ceramic substrate 12 is preferably defined by a stack of mother ceramic layers 12a, 12b, and 12c. Where necessary, a layer of nickel plating (first layer) and a layer of palladium or gold plating (second layer) are preferably formed by electrolytic plating, for example, on the surface of the conductive shield layer 13.

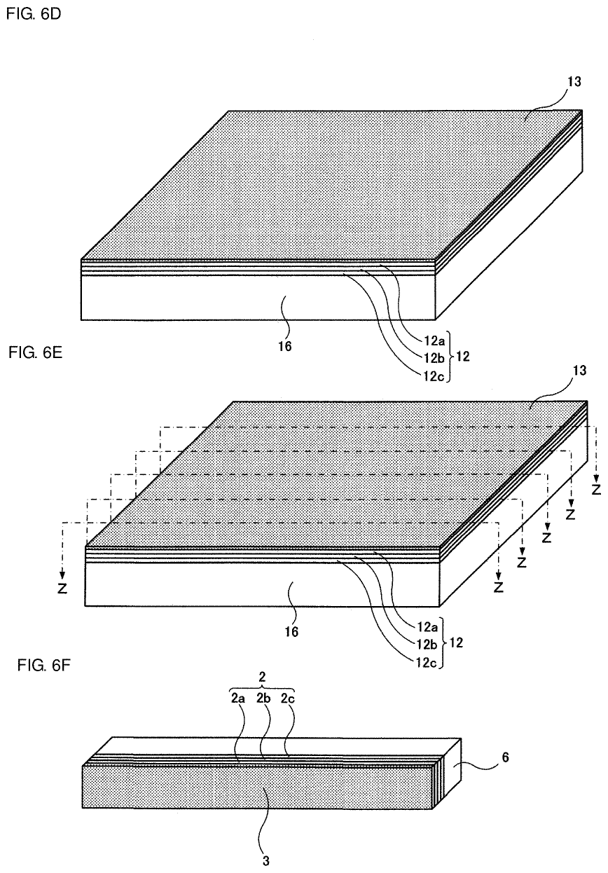

Next, as illustrated in FIG. 6D, the mother ceramic substrate 12 including the conductive shield layer 13 formed thereon is attached to a resin layer 6. In the present preferred embodiment, an approximately 600-μm-thick polyethylene terephthalate (PET) layer, for example, slightly sticky on the upper principal surface thereof is preferably used as the resin layer 6. The resin layer 6 may be of any material and thickness, and is not limited to that described above.

Next, as illustrated in FIG. 6E, the conductive shield layer 13, the mother ceramic substrate 12, and the resin layer 6 are preferably cut along dot-and-dash arrows Z, that is, cut in the stacking direction of the resin layer 6 and the mother ceramic substrate 12. As illustrated in FIG. 6F, each of the resulting ceramic plates 2 includes the conductive shield layer 3 on one principal surface thereof and a resin layer 6 on the other principal surface thereof. Note that the ceramic plate 2 illustrated in FIG. 6F is in a position reached by rotating the ceramic plate 2 by 90° about its longitudinal axis after the cutting.

The ceramic plate 2 is preferably about 100 μm thick, for example. The conductive shield layer 3 is preferably about 20 μm thick, for example. The resin layer 6 is preferably about 600 μm thick, for example. That is, the total thickness of the ceramic plate 2, the conductive shield layer 3, and the resin layer 6 is preferably about 720 μm, for example. The ceramic plate 2 (the conductive shield layer 3, the resin layer 6) is preferably about 700 μm high, for example. The length of the ceramic plate 2 (the conductive shield layer 3, the resin layer 6) is appropriately selected as necessary. The sum of the thickness of the ceramic plate 2 and the thickness of the resin layer 6 is preferably longer than the height of the ceramic plate 2. This enables stable mounting of the ceramic plate 2 onto a mother circuit board 11. Note that the height of the ceramic plate 2 is the width of pieces into which the conductive shield layer 13, the mother ceramic substrate 12, and the resin layer 6 are cut.

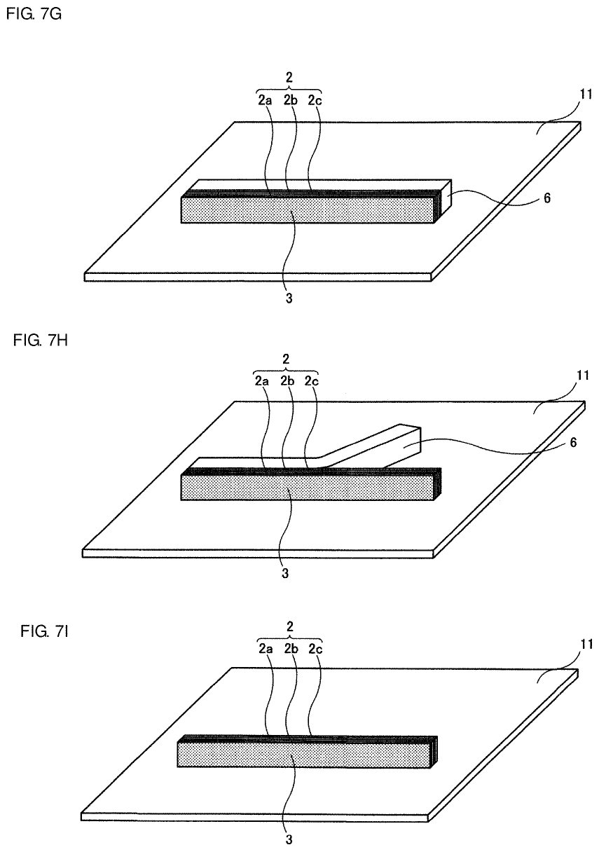

Next, as illustrated in FIG. 7G, the ceramic plate 2 including the conductive shield layer 3 on one principal surface thereof and the resin layer 6 on the other principal surface thereof is mounted onto the mother circuit board 11. To produce many electronic circuit modules 100 together, the mother circuit board 11 includes many circuit boards 1 arranged in a matrix. While not shown, the mother circuit board 11 includes, on the lower principal surface thereof, outer electrodes used to mount the electronic circuit modules 100, for example, on circuit boards of electronic devices, and also includes, on the upper principal surface thereof, mounting electrodes used to mount the electronic components 4. The outer electrodes and the mounting electrodes are electrically connected.

For example, an adhesive is used to mount the ceramic plate 2 on the mother circuit board 11. Alternatively, when the lower end surface of the ceramic plate 2 includes electrodes (e.g., conductive vias) formed in advance, the electrodes may be joined with solder or conductive adhesive to the mounting electrodes formed on the upper principal surface of the mother circuit board 11.

In the step of mounting the ceramic plate 2 on the mother circuit board 11, the ceramic plate 2 is prevented from falling over, because the resin layer 6 with a thickness of about 600 μm supports the ceramic plate 2 with a thickness of about 100 μm (including the conductive shield layer 3 with a thickness of about 20 μm formed on the principal surface thereof). This makes it very easy to perform the step of mounting the ceramic plate 2 on the mother circuit board 11. After the mounting, the principal surface of the ceramic plate 2 is perpendicular or substantially perpendicular to the principal surface of the mother circuit board 11.

As illustrated in FIG. 7H, after mounting the ceramic plate 2 as required on the mother circuit board 11, the resin layer 6 having an elongated shape is peeled off the ceramic plate 2 continuously from one end portion thereof. Thus, as illustrated in FIG. 7I, only the ceramic plate 2 (including the conductive shield layer 3 on the principal surface thereof) is left unremoved on the principal surface of the mother circuit board 11.

Next, while not shown (and the same applies to the following description), the electronic components 4 are preferably mounted on the upper principal surface of the mother circuit board 11. When solder or conductive adhesive is used to mount the ceramic plates 2, the ceramic plates 2 and the electronic components 4 may be mounted at the same time.

Then, the mother circuit board 11 including the ceramic plates 2 and the electronic components 4 mounted thereon is cut into individual circuit boards 1.

Last, the lid member 5 made of metal is joined to the upper end surfaces of the ceramic plates 2 (case outer periphery members) to complete the electronic circuit module 100.

### Second Preferred Embodiment

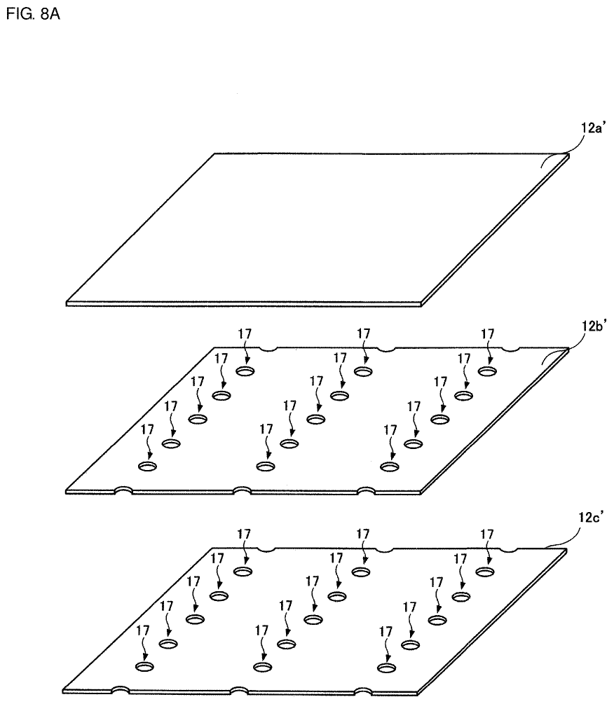

FIG. 8A to FIG. 11F illustrate an electronic circuit module manufacturing method according to a second preferred embodiment of the present invention. The ceramic plates 2 made in the second preferred embodiment each include conductive vias 7 on the lower end surface thereof joined to the circuit board 1 and the upper end surface thereof to which the lid member 5 is joined. The conductive vias 7 on the upper and lower sides are electrically connected by wiring electrodes inside the ceramic plate 2.

The electronic circuit module manufacturing method according to the second preferred embodiment is obtained by adding another step to the electronic circuit module manufacturing method according to the first preferred embodiment.

First, the ceramic green sheets 12a′, 12b′, and 12c′ are prepared. Then in the second preferred embodiment, as illustrated in FIG. 8A, through holes 17 that define the conductive vias 7 are formed in the ceramic green sheets 12b′ and 12c′. The through holes 17 are preferably formed, for example, by laser irradiation, or are punched with a die. The ceramic green sheet 12a′ does not include any through holes formed therein.

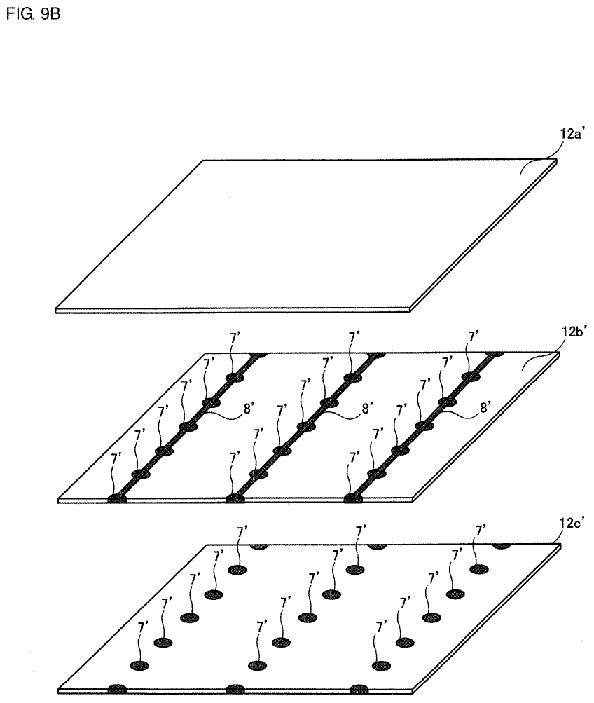

Next, the through holes 17 formed in the ceramic green sheets 12b′ and 12c′ are filled with conductive paste 7′, as illustrated in FIG. 9B. At the same time, conductive paste is applied onto the upper principal surface of the ceramic green sheet 12b′ to form wiring electrode patterns 8′ to connect adjacent points of the conductive paste 7′ in the through holes 17. Other wiring electrode patterns may be additionally provided to connect the wiring electrode patterns 8′.

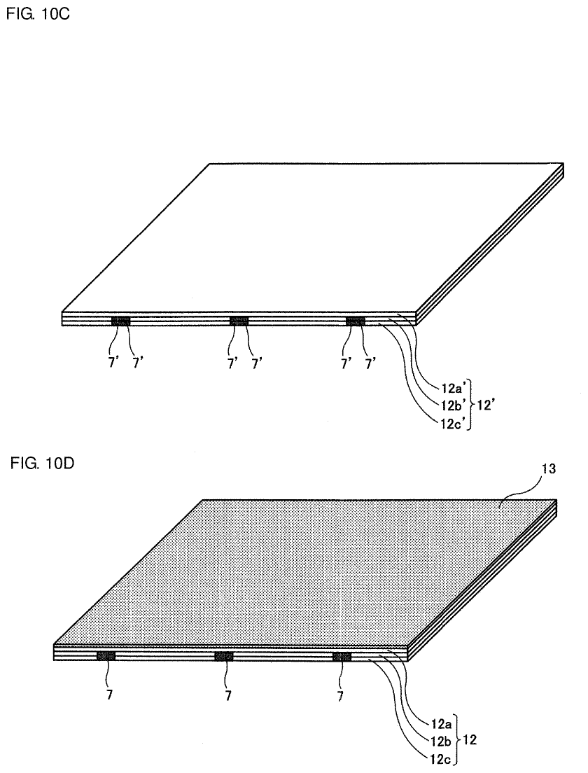

Next, as illustrated in FIG. 10C, the ceramic green sheets 12a′, 12b′, and 12c′ are stacked, pressed, and heated to obtain the unfired mother ceramic substrate 12′.

After application of copper paste to one principal surface of the unfired mother ceramic substrate 12′, the entire unfired mother ceramic substrate 12′ is fired to obtain, as illustrated in FIG. 10D, the mother ceramic substrate 12 including the conductive shield layer 13 on one principal surface thereof. The conductive paste 7′ in the through holes 17 is thus fired to form the conductive vias 7 penetrating the mother ceramic layers 12b and 12c. At the same time, the wiring electrode patterns 8′ are fired to form the wiring electrodes (not shown).

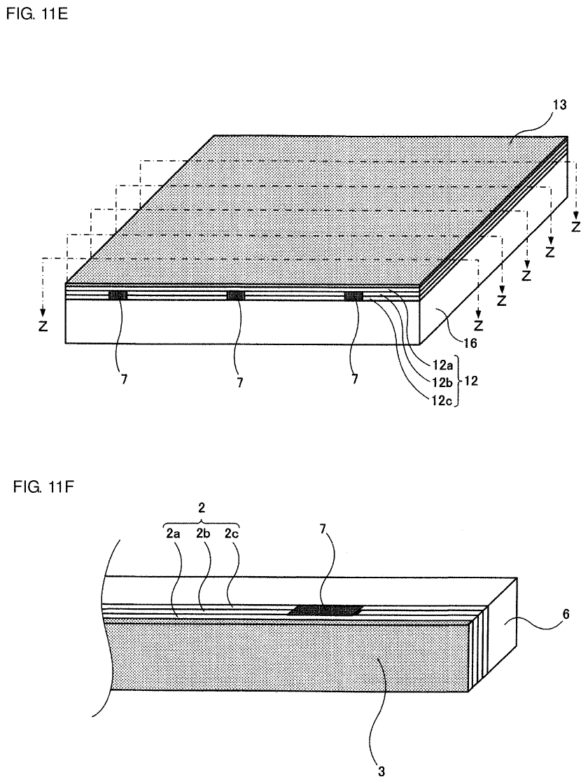

Then, as illustrated in FIG. 11E, after the mother ceramic substrate 12 including the conductive shield layer 13 formed thereon is attached to the resin layer 6, the conductive shield layer 13, the mother ceramic substrate 12, and the resin layer 6 are cut along dot-and-dash arrows Z.

Thus, as illustrated in FIG. 11F, the ceramic plate 2 including the conductive shield layer 3 on one principal surface thereof and the resin layer 6 on the other principal surface thereof is obtained. The ceramic plate 2 includes the conductive via 7 on the upper end surface thereof to which the lid member 5 is joined, and also includes the conductive via 7 (not shown) on the lower end surface thereof joined to the circuit board 1. The conductive vias 7 on the upper and lower sides are electrically connected by the wiring electrodes (not shown) inside the ceramic plate 2.

Next, while not shown (and the same applies to the following description), the ceramic plates 2, each including the conductive shield layer 3 on one principal surface thereof and the resin layer 6 on the other principal surface thereof, are mounted on the mother circuit board 11. To mount the ceramic plates 2 on the mother circuit board 11, the conductive vias 7 exposed in their cross-sections on the lower end surfaces of the ceramic plates 2 are joined, with solder or conductive adhesive, to the mounting electrodes on the upper principal surface of the mother circuit board 11. In this step, where the resin layer 6 supports the ceramic plate 2 (including the conductive shield layer 3 formed thereon), the ceramic plate 2 is prevented from falling over. In this step, the conductive shield layer 3 formed on the ceramic plate 2 is preferably connected to the ground electrode formed on the mother circuit board 11.

Next, the resin layer 6 having an elongated shape is removed from the ceramic plate 2.

Next, the electronic components 4 are mounted on the upper principal surface of the mother circuit board 11.

Then, the mother circuit board 11 including the ceramic plates 2 and the electronic components 4 mounted thereon is cut into individual circuit boards 1.

Last, the lid member 5 made of metal is joined to the upper end surfaces of the ceramic plates 2 (case outer periphery members) to complete the electronic circuit module. To join the lid member 5 made of metal to the ceramic plates 2, the lid member 5 made of metal is joined, with solder or conductive adhesive, to the conductive vias 7 exposed in their cross-sections on the upper end surfaces of the ceramic plates 2. The lid member 5 made of metal is connected to the ground electrode formed on the circuit board 1, with the conductive vias 7 on the upper end surfaces of the ceramic plates 2, the wiring electrodes, and the conductive vias 7 on the lower end surfaces of the ceramic plates 2 interposed therebetween.

### Third Preferred Embodiment

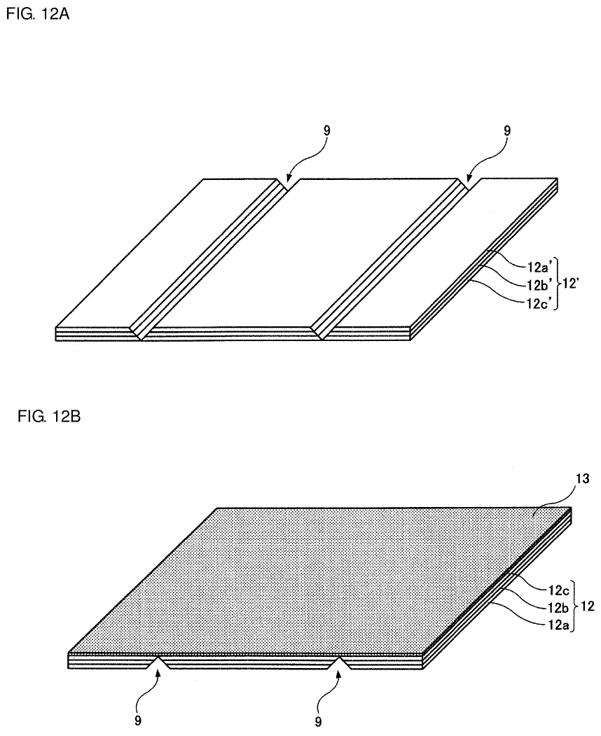

FIG. 12A to FIG. 14F illustrate an electronic circuit module manufacturing method according to a third preferred embodiment of the present invention. The ceramic plates 2 made in the third preferred embodiment each preferably include V-shaped grooves 9 formed in one principal surface thereof.

The electronic circuit module manufacturing method according to the third preferred embodiment is also obtained by adding another step to the electronic circuit module manufacturing method according to the first preferred embodiment.

In the third preferred embodiment, first, as illustrated in FIG. 12A, the V-shaped grooves 9 are provided in the unfired mother ceramic substrate 12′ by stacking the ceramic green sheets 12a′, 12b′, and 12c′. The grooves 9 are preferably formed by, for example, laser irradiation, or are punched with a die. The grooves 9 each include a bottom, and are open on the side of the ceramic green sheet 12a′ and closed on the side of the ceramic green sheet 12c′. The inner surfaces of each groove 9 are inclined to define an angle of 90° therebetween.

Although the grooves 9 each having a bottom are formed in the unfired mother ceramic substrate 12′ in the present preferred embodiment, the grooves 9 may be replaced with slits that penetrate between both principal surfaces.

After application of copper paste to the ceramic green sheet 12c′ of the unfired mother ceramic substrate 12′, the entire unfired mother ceramic substrate 12′ is fired to obtain, as illustrated in FIG. 12B, the mother ceramic substrate 12 having the conductive shield layer 13 formed thereon.

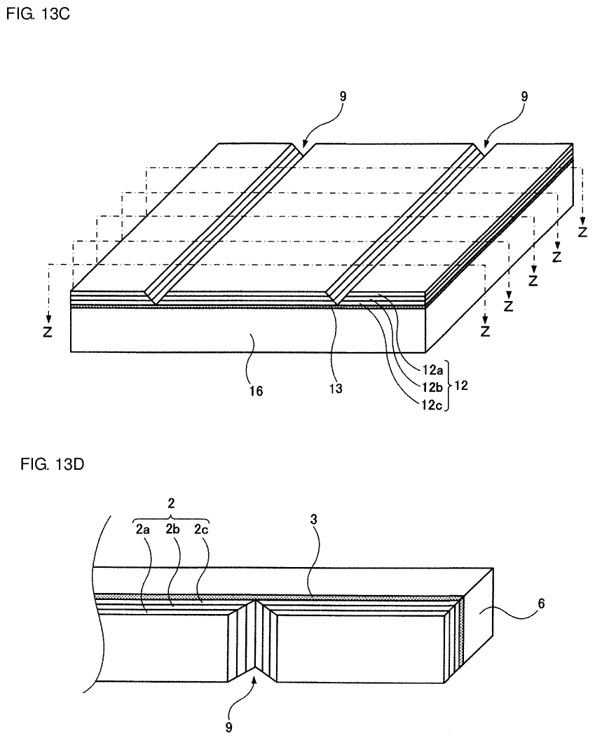

Next, as illustrated in FIG. 13C, the mother ceramic substrate 12 is attached to the resin layer 6, on one side thereof including the conductive shield layer 13 thereon. Then, the mother ceramic substrate 12, the conductive shield layer 13, and the resin layer 6 are cut along dot-and-dash arrows Z. The resin layer 6 having flexibility is used in the present preferred embodiment.

Thus, as illustrated in FIG. 13D, the ceramic plate 2 including the conductive shield layer 3 and the resin layer 6 on one principal surface thereof is obtained. The other principal surface of the ceramic plate 2 made as described above includes the V-shaped grooves 9.

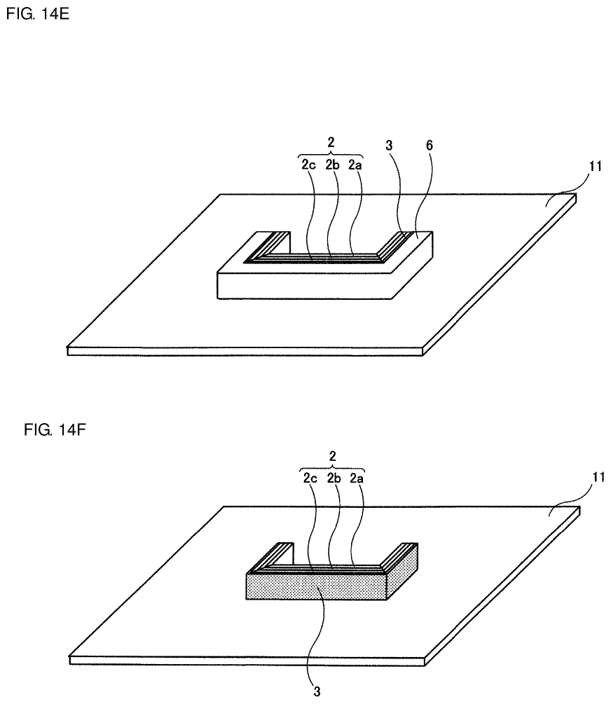

Next, as illustrated in FIG. 14E, the ceramic plate 2 including the conductive shield layer 3 and the resin layer 6 on one principal surface thereof is bent at the V-shaped grooves 9 into an approximately 90° angle and mounted on the mother circuit board 11. Since the grooves 9 each are formed in advance such that the inner surfaces thereof are inclined to define an angle of 90° therebetween, the ceramic plate 2 is bent into an approximately 90° angle. Although the bending creates cracks in the ceramic plate 2 and the conductive shield layer 3, the grooves 9 formed in advance allow the ceramic plate 2 and the conductive shield layer 3 to crack in a very orderly manner. Bending the ceramic plate 2 allows deformation of the resin layer 6 having flexibility.

In the step of mounting the ceramic plate 2 on the mother circuit board 11, the resin layer 6 supports the ceramic plate 2 (including the conductive shield layer 3 thereon), so that the ceramic plate 2 is prevented from falling over.

Next, the resin layer 6 is removed from the ceramic plate 2, as illustrated in FIG. 14F.

Next, while not shown (and the same applies to the following description), the electronic components 4 are mounted on the upper principal surface of the mother circuit board 11.

Then, the mother circuit board 11 including the ceramic plates 2 and the electronic components 4 mounted thereon is cut into individual circuit boards 1.

Last, the lid member 5 made of metal is joined to the upper end surfaces of the ceramic plates 2 (case outer periphery members) to complete the electronic circuit module.

The angle defined between the inclined inner surfaces is not limited to approximately 90°. By setting the inclination of opposite inner surfaces of each groove in accordance with the bend angle, the ceramic plate 2 can be easily mounted in a complex shape. For example, when the inner surfaces are inclined to define an angle of about 30° therebetween, the ceramic plate 2 can be easily bent into an angle of approximately 150°. Also, for example, when the inner surfaces are inclined to define an angle of about 150° therebetween, the ceramic plate 2 can be easily bent into an angle of about 30°.

### Fourth Preferred Embodiment

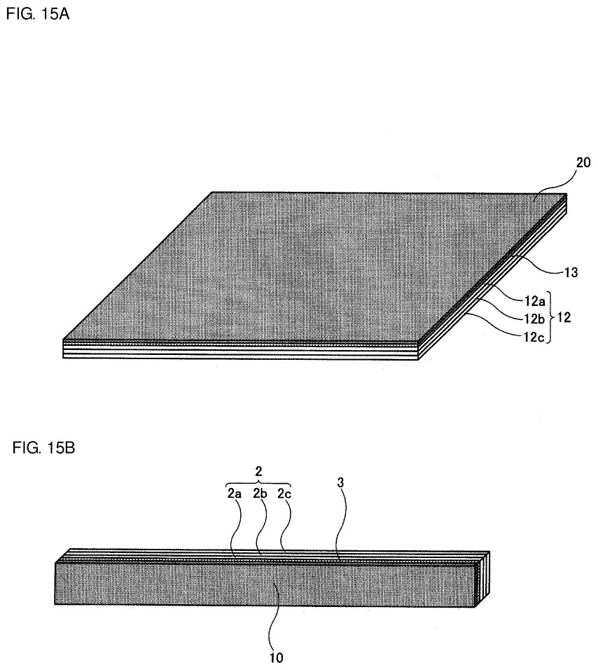

FIGS. 15A and 15B illustrate an electronic circuit module manufacturing method according to a fourth preferred embodiment of the present invention. The ceramic plates 2 made in the fourth preferred embodiment each preferably include a graphite layer 10 on the conductive shield layer 3 on one principal surface thereof.

The electronic circuit module manufacturing method according to the fourth preferred embodiment is obtained by adding another step to the electronic circuit module manufacturing method according to the first preferred embodiment. The following description primarily refers to the added elements.

In the fourth preferred embodiment, as illustrated in FIG. 15A, a graphite sheet is attached to the entire or substantially the entire principal surface of the conductive shield layer 13 formed on one principal surface of the mother ceramic substrate 12, so as to form a graphite layer 20. Other configurations of the electronic circuit module manufacturing method according to the fourth preferred embodiment are preferably the same or substantially the same as those of the electronic circuit module manufacturing method according to the first preferred embodiment. The graphite layer 20 does not necessarily need to be formed by the method described above, and may be formed, for example, by sputtering.

As illustrated in FIG. 15B, the ceramic plate 2 made in the fourth preferred embodiment is preferably provided with the graphite layer 10 (which is one of pieces into which the graphite layer 20 is cut) on the principal surface of the conductive shield layer 3 on one principal surface of the ceramic plate 2. In the ceramic plate 2 made in the fourth preferred embodiment, a very high heat dissipation effect of the graphite layer 10 prevents the ceramic plate 2 and the conductive shield layer 3 from being heated to a high temperature.

The electronic circuit module manufacturing methods according to the first to fourth preferred embodiments have been described. The present invention is not limited to the preferred embodiments described above, and various changes can be made thereto in accordance with the spirit of the invention.

For example, although the ceramic plates 2 presented in the first to fourth preferred embodiments preferably have a multilayer structure formed by stacking the three ceramic layers 2a, 2b, and 2c, the ceramic plates 2 may have a single-layer structure formed by one ceramic layer. Although the mother circuit board 11 presented in the first to fourth preferred embodiments includes many circuit boards 1 arranged in a matrix, the mother circuit board is not limited to this and may be configured to be used as a single circuit board.

Although the ceramic plates 2 presented in the first to fourth preferred embodiments each include the conductive shield layer 3 on one principal surface thereof, the conductive shield layer 3 is optional and may be removed.

Although a magnetic ceramic material (magnetic ferrite ceramic material) is used to form the ceramic plates 2 in the first to fourth preferred embodiments, the ceramic plates 2 may be made of any material, and a non-magnetic ceramic material may be used.

Although the ceramic plates 2 presented in the first to fourth preferred embodiments each include the resin layer 6 only on one principal surface thereof, the resin layer 6 may be on each of the principal surfaces. When provided only on one principal surface, the resin layer 6 may be on either of the principal surfaces.

Although the lid member 5 made of metal is used in the first to fourth preferred embodiments, the ceramic plate 2 including the conductive shield layer 3 on one principal surface thereof may be used as the lid member.

In any of the electronic circuit modules 100, 200, and 300 described in the first preferred embodiment, the case outer periphery members defined by the ceramic plates 2 are arranged in the shape of a rectangle or a substantial rectangle in plan view. However, the case outer periphery members do not necessarily need to be arranged in the shape of a rectangle or a substantial rectangle, and may have a more complex structure. That is, with present invention, the case outer periphery members can be easily arranged in a complex shape.

Although the conductive vias 7 and the conductive shield layer 3 are preferably not electrically connected in the second preferred embodiment, they may be configured to be electrically connected if so desired.

Although the ceramic plates 2 presented in the third preferred embodiment include the grooves 9 each including a bottom, the grooves 9 may be replaced with slits penetrating between both principal surfaces.

Although the grooves 9 presented in the third preferred embodiment are provided in the unfired mother ceramic substrate 12′, the grooves 9 may be provided in the mother ceramic substrate 12 after firing.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An electronic circuit module manufacturing method for manufacturing an electronic circuit module that includes a circuit board and a ceramic plate mounted on the circuit board, the method comprising:
making a mother ceramic substrate by firing;
forming a resin layer on at least one principal surface of the mother ceramic substrate;
cutting the mother ceramic substrate including the resin layer thereon in a stacking direction of the resin layer and the mother ceramic substrate into pieces, each of the pieces including the ceramic plate with the resin layer thereon;
mounting the ceramic plate including the resin layer thereon on a principal surface of the circuit board such that a principal surface of the ceramic plate is perpendicular or substantially perpendicular to the principal surface of the circuit board; and
removing the resin layer from the principal surface of the ceramic plate mounted on the circuit board.

2. The electronic circuit module manufacturing method according to claim 1, further comprising forming a conductive shield layer on at least one principal surface of the mother ceramic substrate.

3. The electronic circuit module manufacturing method according to claim 2, wherein the forming the resin layer is preceded by the forming the conductive shield layer, and the resin layer is formed on the conductive shield layer.

4. The electronic circuit module manufacturing method according to claim 2, further comprising forming a graphite layer on a principal surface of the conductive shield layer on the mother ceramic substrate.

5. The electronic circuit module manufacturing method according to claim 4, wherein the forming the resin layer is preceded by the forming the graphite layer, and the resin layer is formed on the graphite layer.

6. The electronic circuit module manufacturing method according to claim 1, wherein the mother ceramic substrate is a multilayer substrate formed by stacking a plurality of ceramic layers.

7. The electronic circuit module manufacturing method according to claim 1, wherein the mother ceramic substrate is made of a magnetic ceramic material.

8. The electronic circuit module manufacturing method according to claim 1, wherein the ceramic plate mounted on the circuit board is a case outer periphery member or a case inner partition.

9. The electronic circuit module manufacturing method according to claim 1, wherein
the making the mother ceramic substrate includes forming a conductive via in the mother ceramic substrate; and
the cutting the mother ceramic substrate into pieces allows a cross-section of the conductive via to be exposed on at least one of a first end surface and a second end surface of the ceramic plate, the first end surface being an end surface to be mounted on the circuit board, the second end surface being opposite the first end surface.

10. The electronic circuit module manufacturing method according to claim 9, wherein
cross-sections of different conductive vias are exposed on the respective first and second end surfaces of the ceramic plate, the first end surface being an end surface to be mounted on the circuit board, the second end surface being opposite the first end surface; and
the making the mother ceramic substrate includes forming a wiring electrode in the mother ceramic substrate, the wiring electrode connecting the different conductive vias.

11. The electronic circuit module manufacturing method according to claim 1, further comprising:
forming at least one of a slit and a groove in a principal surface of an unfired mother ceramic substrate before the mother ceramic substrate is made by firing, or in the at least one principal surface of the mother ceramic substrate after the mother ceramic substrate is made by firing, the slit penetrating between both principal surfaces, the groove opening on one principal surface; wherein
at least one of the slit and the groove is formed in each of the ceramic plates formed by the cutting; and
the mounting the ceramic plate on the circuit board includes bending the ceramic plate at the slit or groove before the ceramic plate is mounted on the circuit board.

12. The electronic circuit module manufacturing method according to claim 11, wherein opposite inner surfaces of the slit, or opposite inner surfaces of the groove, are inclined to define an angle of about 90° therebetween.

13. The electronic circuit module manufacturing method according to claim 1, wherein the removing the resin layer from the principal surface of the ceramic plate mounted on the circuit board includes continuously peeling off the resin layer formed in an elongated shape on the principal surface of the ceramic plate, the peeling starting at one end portion of the resin layer.

14. An electronic circuit module, comprising:
a circuit board including a principal surface;
an electronic component mounted on the principal surface of the circuit board; and
a wall portion mounted on the principal surface of the circuit board, the wall portion surrounding the electronic component; wherein
the wall portion includes a bottom surface adjacent to and opposing the principal surface of the circuit board, a top surface opposite the bottom surface, and a plurality of side surfaces connecting the bottom surface to the top surface; and
the wall portion includes a multilayer structure including a plurality of ceramic layers that are stacked, and the side surfaces of the wall portion are perpendicular or substantially perpendicular to the principal surface of the circuit board.

15. The electronic circuit module according to claim 14, wherein the wall portion includes a conductive shield layer on at least one of the side surfaces in a pair, the side surfaces being opposite in a stacking direction of the plurality of ceramic layers.

16. The electronic circuit module according to claim 15, further comprising a graphite layer on the conductive shield layer.

17. The electronic circuit module according to claim 14, wherein the plurality of ceramic layers include magnetic ferrite.

18. The electronic circuit module according to claim 14, wherein the wall portion is a case outer periphery member or a case inner partition.

19. The electronic circuit module according to claim 14, wherein
the wall portion includes a conductive via; and
a cross-section of the conductive via is exposed on at least one of the bottom surface and the top surface of the wall portion.

20. The electronic circuit module according to claim 19, wherein
cross-sections of different conductive vias are exposed on the respective bottom and top surfaces of the wall portion; and
the wall portion includes a wiring electrode connecting the different conductive vias.

21. The electronic circuit module according to claim 14, wherein
the electronic circuit module includes a plurality of wall portions; and
the plurality of wall portions include respective portions extending in different directions in a plan view, the portions being in contact with each other at respective ends of the wall portions.
